(19) United States
(12) Patent Application Publication
(10) Pub. No.: US 2003/0057937 A1
(43) Pub. Date: Mar. 27, 2003

(54) Testing of SOC

(76) Inventors: Vinod Nair Gopikuttan Nair, Singapore (SG); Shridhar Mubaraq Mishra, Singapore (SG)

Correspondence Address: Siemens Corporation, Intellectual Property Department, 186 Wood Avenue South, Iselin, NJ, 08830, US

(21) Appl. No.: 09/964,204

(22) Filed: Sep. 26, 2001

(51) Int. Cl. G01R 23/04; G01R 25/02; G01R 27/02

(52) U.S. Cl. 324/95

(57) ABSTRACT

The present invention relates to a communication circuit arrangement (1) providing a testing functionality. A switch (10) couples internal circuit nodes of a transmission path (2) and a receiver path (3) of an interface communication circuit (1), thereby providing a test signal loop. By feeding a test signal (A) into an input terminal (11) of a transmission path (2) and comparing this original signal (A) with a received signal (B) from output terminal (14) of receiver path (3), functional faults of the circuit are revealed at early development stages. The test method is preferably applicable in communication devices.

### BACKGROUND OF THE INVENTION

The present invention relates to a communication circuit arrangement with bidirectional signal paths and to a method of testing a communication circuit arrangement.

Communication circuits normally are provided to process data according to layers 1 to 3 of the OSI protocol, including efficient processing of data, performing channel coding and decoding and providing fast framing and deframing capabilities.

Testing of communication devices, for example ISDN interfaces, which transmit and/or receive audio or video data, usually is a difficult task due to the complexity of the system. In many cases, the functionality of such circuits can be verified only per individual functional blocks.

Successively testing individual blocks of a communication circuit however takes much effort and time.

### SUMMARY OF THE INVENTION

It is an object of the present invention to provide a communication circuit arrangement with bidirectional signal paths which allows simple testing of the functionality of the whole communication circuit without much effort.

According to the present invention, a communication circuit arrangement with bidirectional signal paths is provided. The circuit arrangement comprises

a first signal path to transmit a first signal into a first direction, having an input terminal and an output terminal and including a first digital circuit block to process said first signal,

a second signal path to transmit a second signal into a second direction having an input terminal and an output terminal and including a second digital circuit block to process said second signal, and

a first switch having a first terminal coupled to a first circuit node within the first signal path and a second terminal coupled to a second circuit node within the second signal path to provide a test signal loop during a test mode of said circuit arrangement.

A communication circuit normally comprises a transmitting signal path and a receiving signal path. Introducing a switch coupled between transmission and reception signal paths provides a test signal loop. This test signal loop can then be fed with a test signal at the input terminal of the first signal path which can then be compared to a signal received from the output terminal of the second signal path of the given communication circuit.

With this approach, signal processing faults like synchronisation defects can easily be detected by comparing transmitted and received test signals with each other. For example, deviations from an ideal duty cycle or latency times or phase differences or glitches, especially when analysed visually, provide a detailed and fast method of detecting data losses or other errors in complex communication circuits.

The method described can be performed at very early circuit development levels. For example, a design engineer can verify the functionality of a circuit design even at the VHDL level, thus reducing costs.

According to a preferred embodiment of the present invention, transmission and receiver signal paths comprise an analog circuit block each, for example to provide an analog transceiver front end having, for example, a radio frequency interface. In this case, it is preferable to provide the first switch for building a test signal loop between analog and digital circuit blocks of transmission and receiving signal paths.

In a further, preferred embodiment of the present invention, second and third switches are provided to disconnect the analog circuitry from the digital parts under test while closing the data loop using the first switching device.

Further advantageous features, aspects and details of the invention are evident from the dependent claims.

### BRIEF DESCRIPTION OF THE DRAWINGS

FIG. 1a shows a simplified structural diagram of a first embodiment of a communication circuit according to the present invention;

FIG. 1b shows input and output test signals according to the communication circuit of FIG. 1a;

FIG. 2a shows the block diagram according to FIG. 1a; and

FIG. 2b shows input and output test signals according to the circuit of FIG. 2a.

### PREFERRED EMBODIMENTS OF THE INVENTION

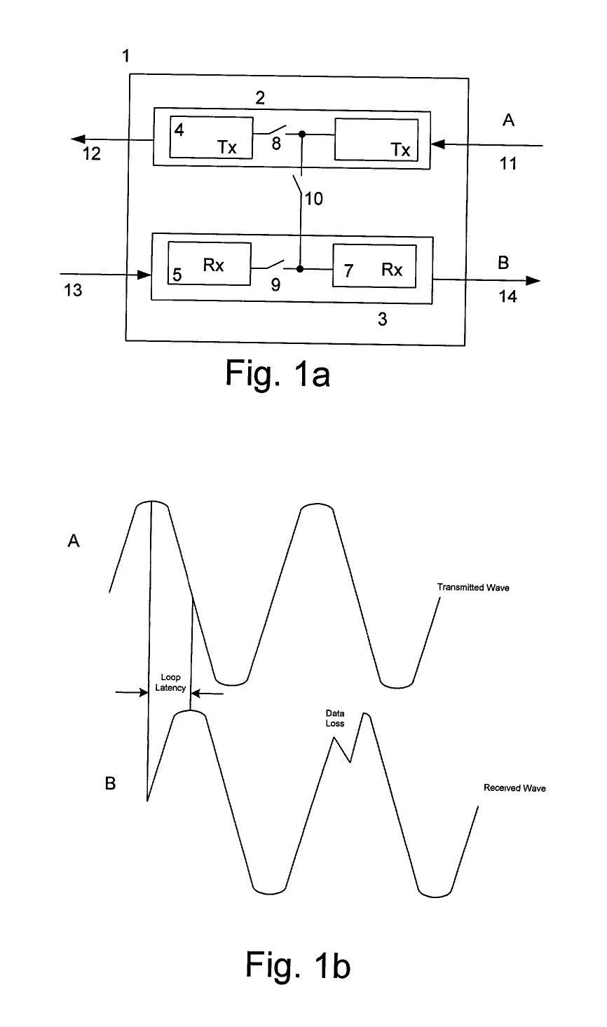

FIG. 1a shows a communication circuit 1 having a first signal path 2 for transmission of a signal and a receiver path 3 to receive a signal from, for example, a common bus or a radio front end of a transceiver. Transmission 2 as well as receiver path 3 each comprise analog circuitry 4, 5 and digital circuitry 6, 7.

The transmission path 2 further comprises a switching element 8 to disconnect analog and digital circuitry 4, 6. The receiver path 3 also comprises a switching element 9 connected between analog and digital circuitry 5, 7. Another switching element 10 is connected with one terminal between the switch within the transmission path 2 and the digital part 6 of transmission path 2. A second terminal of switch 10 is connected between switch 9 and digital circuitry 7 within receiver path 3.

In normal operation mode, switches 8 and 9 are closed while switch 10 is in an open position. In this operation mode, data to send over interface 1, for example from a communication device like a telephone etc., is fed into input terminal 11 of transmission path 2. This signal is then processed within the digital circuitry 6 including channel coding, framing, and other processes. The analog circuit 4 provides RF conversion of the coded and framed signal and feeds the RF signal into an antenna via output terminal 12 of transmission path 2.

A received RF signal is provided at input terminal 13 of receiver path 3. This signal is then processed, for example down converted to a baseband signal, within analog circuit 5 of receiver path 3. This baseband signal is then digitally processed within digital circuitry 7 comprising process steps like channel decoding and fast deframing. The decoded, digital signal is finally provided at output terminal 14 of receiver path 3.

In a normal operation mode of the interface 1, switches 8 and 9 are in a closed position, while switch 10 is in an open position.

In a test mode according to the present invention, switch 10 is closed to couple internal circuit nodes within transmission path 2 and receiver path 3.

Herewith, a test data loop between input terminal 11 and output terminal 14 of communication circuit 1 is provided. To reduce signal distortion, switches 8 and 9 can be opened to decouple circuitry not intended to test and not arranged within the test loop.

To provide testing functionality, a test signal A can now be fed into input terminal 11 after quantization of the test signal. A test signal A can, for example, be a sinus wave or a square wave with defined duty cycle of, for example, 50%, which means that corresponding logical high and low signal times are equal to each other. In this case, a symmetric square wave is provided.

By comparing a signal B received from output terminal 14 and reconverting this signal into a time continuous harmonic signal, faults like data losses or synchronisation errors between input terminal 11 and output terminal 14 are revealed. These errors lead to glitches within the received signal. The phase difference between transmitted and received wave A, B reveals the latency of the data loop.

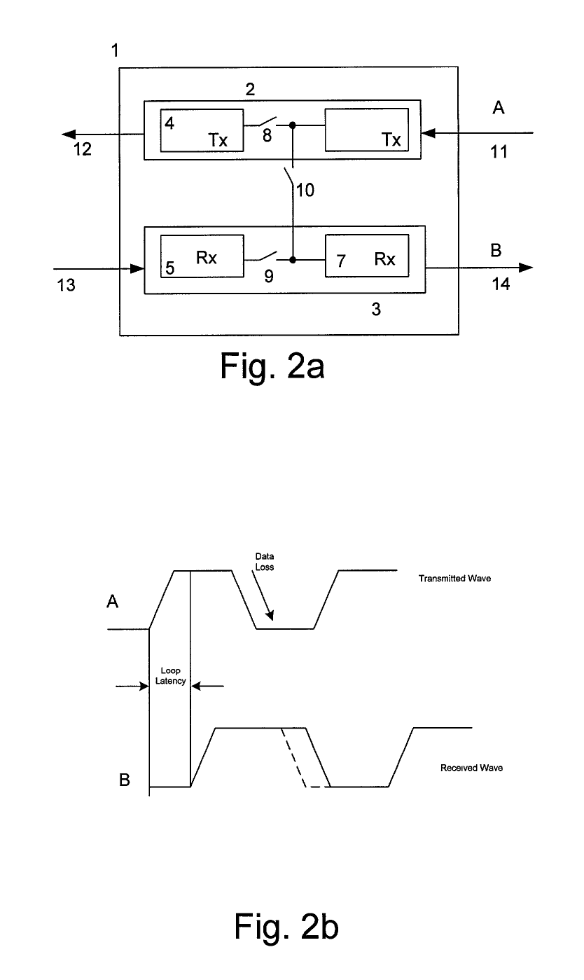

FIG. 2a shows a communication circuit 1 according to the one shown in FIG. 1a, therefore, the description shall not be repeated. The difference, however, is that instead of test signals A and B according to FIG. 1a, FIG. 2a shows a communication circuit 1 tested with a test signal C and providing a received signal D, wherein signals C and D are 50% duty cycle square waves having limited slope. In this case, synchronisation failures and data losses, respectively, are revealed by any deviation from the 50% duty cycle of the original wave fed into input terminal 11. The loop latency of circuit 1 can again be detected from the phase difference between input and output signals C, D.

The communication circuit arrangement and test method to test the communication circuit for functionality described above allows simple and quick testing of a complex communication circuit interface. The testing described can easily be performed at early development or design stages of communication circuits. Functional errors of individual circuit blocks within communication circuit 1 can therefore be detected at early stages of the design therefore significantly reducing development cost.

In alternative solutions, switch 10 coupling transmission and receiving paths 2, 3 of communication circuit 1 can be provided between two digital blocks of the circuit 1, which does not necessarily comprise analog circuit parts. Revealing system faults by closing a test data loop at different circuit nodes of transmission path 2 and receiver path 3 leads to quick and easy system fault detection.

What is claimed is:

1. Communication circuit arrangement with bidirectional signal paths, comprising:
a first signal path to transmit a first signal into a first direction, having an input terminal and an output terminal and including a first digital circuit block to process said first signal,
a second signal path to transmit a second signal into a second direction having an input terminal and an output terminal and including a second digital circuit block to process said second signal and
a first switch having a first terminal coupled to a first circuit node within the first signal path and a second terminal coupled to a second circuit node within the second signal path to provide a test signal loop during a test mode of said circuit arrangement.

2. Communication circuit arrangement according to claim 1, wherein said first signal path comprises a first analog circuit block coupled between said first digital circuit block and said output terminal of said first signal path and wherein said second signal path comprises a second analog circuit block coupled between said second digital circuit block and said input terminal of said second signal path.

3. Communication circuit arrangement according to claim 1, wherein said first digital circuit block is a baseband processing block and said first signal path comprises a first analog circuit block to convert said first signal into a radio frequency signal, said first analog circuit block coupled between said first digital circuit block and said output terminal of said first signal path, and wherein said second digital circuit block is a baseband processing block and said second signal path comprises a second analog circuit block to convert a received radio signal into said second signal, said second analog circuit block coupled between said input terminal of said second signal path and said second digital circuit block.

4. Communication circuit arrangement according to claim 1, wherein a second switch is provided having a first terminal connected to said first terminal of said first switch and a second terminal connected to said output terminal of said first signal path and wherein a third switch is provided having a first terminal connected to said input terminal of said second signal path and a second terminal connected to said second terminal of said first switch.
